(19) United States
(12) Patent Application Publication
(10) Pub. No.: US 2007/0283889 A1
(43) Pub. Date: Dec. 13, 2007

(54) APPARATUS OF PROCESSING SUBSTRATE

(75) Inventor: Yong-Hyun Lee, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: JUSUNG ENGINEERING CO., LTD, Gyeonggi-do (KR)

(21) Appl. No.: 11/757,228

(22) Filed: Jun. 1, 2007

(30) Foreign Application Priority Data
Jun. 9, 2006 (KR) 2006-0051887

(51) Int. Cl. C23C 16/00

(52) U.S. Cl. 118/723 E; 118/723 R

(57) ABSTRACT

An apparatus of processing a substrate includes a chamber, a susceptor in the chamber, a plasma-generating unit for generating plasma in the chamber, a power source unit providing power to the plasma-generating unit, and ground lines connected to peripheries of the susceptor, wherein a ratio of a total width of the ground lines to a perimeter of the susceptor is within a range of 2% to 15%.

The present invention claims the benefit of Korean Patent Application No. 10-2006-0051887 filed on Jun. 9, 2006, which is hereby incorporated by references.

### BACKGROUND OF THE INVENTION

1. Field of the Invention

The present invention relates to an apparatus of processing a substrate for semiconductor devices or flat panel display devices, such as wafer or glass, and more particularly an apparatus of processing a substrate that has uniform plasma discharge intensity and forms a thin film of a uniform thickness.

2. Discussion of the Related Art

In general, a semiconductor device or a flat panel display (FPD) device includes a plurality of thin film patterns on a substrate. The thin film patterns are formed by a deposition step of a thin film on the substrate, a photolithographic step using a photoresist, in which the thin film is selectively exposed, and an etch step of the selectively exposed thin film. These steps for a fabrication process of a semiconductor device or an FPD device may be performed using an apparatus for processing a substrate under optimum conditions.

Recently, apparatuses using plasma have been widely used to deposit or etch a thin film. Plasma may be generated by RF (radio frequency) power supplied to a flat electrode or a coil antenna and may be easily affected by electrical properties or circumstances inside a chamber of the apparatus.

FIG. 1 is a view of schematically illustrating an apparatus of processing a substrate using a plasma enhanced chemical vapor deposition (PECVD) method according to the related art.

In FIG. 1, the apparatus 10 includes a chamber 11, and a susceptor 12 is disposed in the chamber 11. A substrate S is loaded on the susceptor 12, and a shaft 12a is connected to a center of the susceptor 12. A gas distributor 13 is disposed over the susceptor 12 in the chamber 11. An exhaust port 19 is formed at a lower wall of the chamber 11.

A flat plasma electrode 14 is disposed over the gas distributor 13 and makes an upper part of the chamber 11 airtight. The gas distributor 13 is fixed to the plasma electrode 14 at edges thereof, and thus a diffusion region 15 is formed between the plasma electrode 14 and the gas distributor 13. A gas inlet 16 is formed at a center of the plasma electrode 14 and is connected to the diffusion region 15. Therefore, gases are injected through the gas inlet 16 and are diffused in the diffusion region 15.

An RF power source 18 is connected to the plasma electrode 14, and a matching system 17 is set up between the plasma electrode 14 and the RF power source 18 to adjust an impedance of RF power.

In the apparatus 10, the susceptor 12, beneficially, is grounded because the susceptor 12 functions as a counter electrode to the plasma electrode 14. A ground line (not shown) may be set up in the shaft 12a and may be connected to the center of the susceptor 12.

By the way, when only the center of the susceptor 12 is grounded, the flow of electric charges may be caused along a path of the side surface of the susceptor 12, the bottom surface of the susceptor 12 and the shaft 12a, as indicated by arrows, due to a potential difference.

More particularly, high frequency currents flow along a surface of a conductor differently from direct currents. Accordingly, it is not enough to ground only the center of the susceptor 12, and there may be potential differences under the susceptor 12.

In addition, an increasing size of the substrate S needs higher RF power to generate plasma and a larger susceptor 12 to be grounded. Moreover, a grounding path of the side surface of the susceptor 12, the bottom surface of the susceptor 12 and the shaft 12a gets longer. Therefore, there may be more potential differences under the susceptor 12.

The potential differences under the susceptor 12 cause plasma discharge, and there is loss of the RF power. The potential differences also badly affect density or uniformity of the plasma over the susceptor 12.

To prevent the problems, other parts of the susceptor have been grounded. That is, ground lines may be connected to peripheries of the susceptor 12. In this case, since the ground lines serve as channels for transferring the RF power provided from the plasma electrode 14, currents flow along the ground lines from the peripheries of the susceptor 12. Therefore, the potential differences may be considerably solved, and the plasma discharge may be prevented under the susceptor 12.

However, as the size of the susceptor 12 gets larger and higher RF power is applied, more ground lines may be connected to the susceptor 12 in order to efficiently ground the susceptor 12. The ground lines may also affect the plasma generated over the susceptor 12.

### SUMMARY OF THE INVENTION

Accordingly, the present invention is directed to an apparatus of processing a substrate that substantially obviates one or more of the problems due to limitations and disadvantages of the related art.

An object of the present invention is to provide an apparatus of processing a substrate that has uniform plasma discharge intensity.

Another object of the present invention is to provide an apparatus of processing a substrate that forms a thin film having a uniform thickness.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus of processing a substrate includes a chamber, a susceptor in the chamber, a plasma-generating unit for generating plasma in the chamber, a power source unit providing power to the plasma-generating unit, and ground lines connected to peripheries of the susceptor, wherein a ratio of a total width of the ground lines to a perimeter of the susceptor is within a range of 2% to 15%.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a view of schematically illustrating an apparatus of processing a substrate using a PECVD method according to the related art;

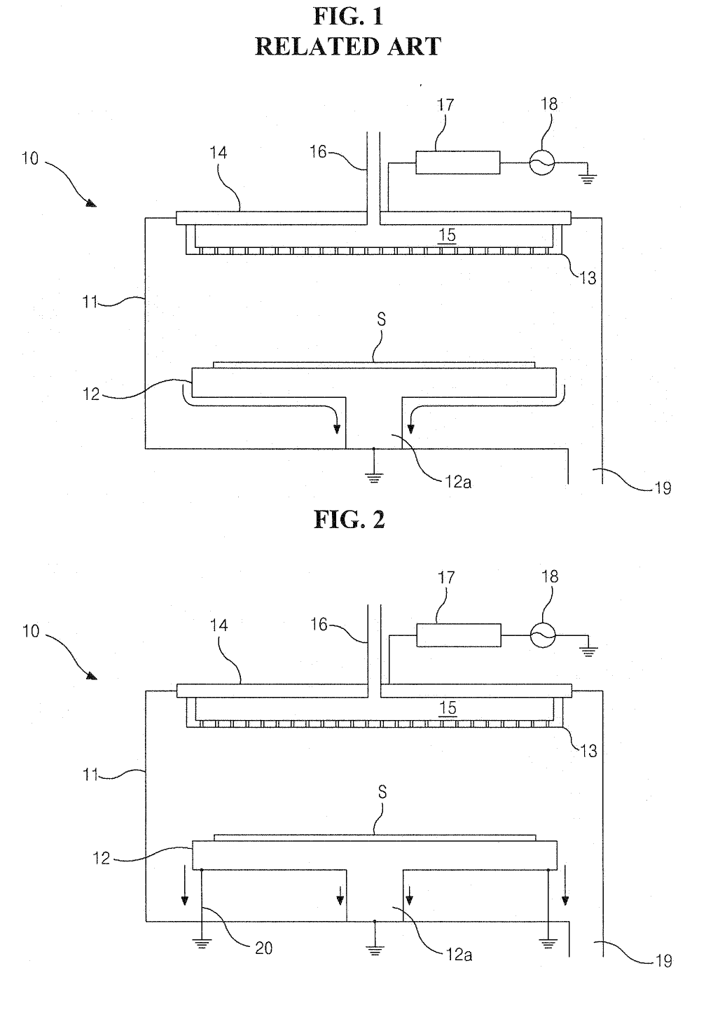

FIG. 2 is a view of schematically illustrating an apparatus of processing a substrate using a PECVD method according to the present invention;

FIG. 3 is a view of schematically illustrating a susceptor and ground lines connected thereto in the apparatus of FIG. 2;

FIG. 4 is a view of illustrating the plasma discharge intensities to the ground line ratios according to an exemplary embodiment of the present invention; and

FIGS. 5A, 5B and 5C are views of illustrating thicknesses of thin films with respect to the ground line ratios according to an exemplary embodiment of the present invention.

### DETAILED DESCRIPTION OF THE PREFERRED EMBODIMENTS

Reference will now be made in detail to the preferred embodiments, an example of which is illustrated in the accompanying drawings.

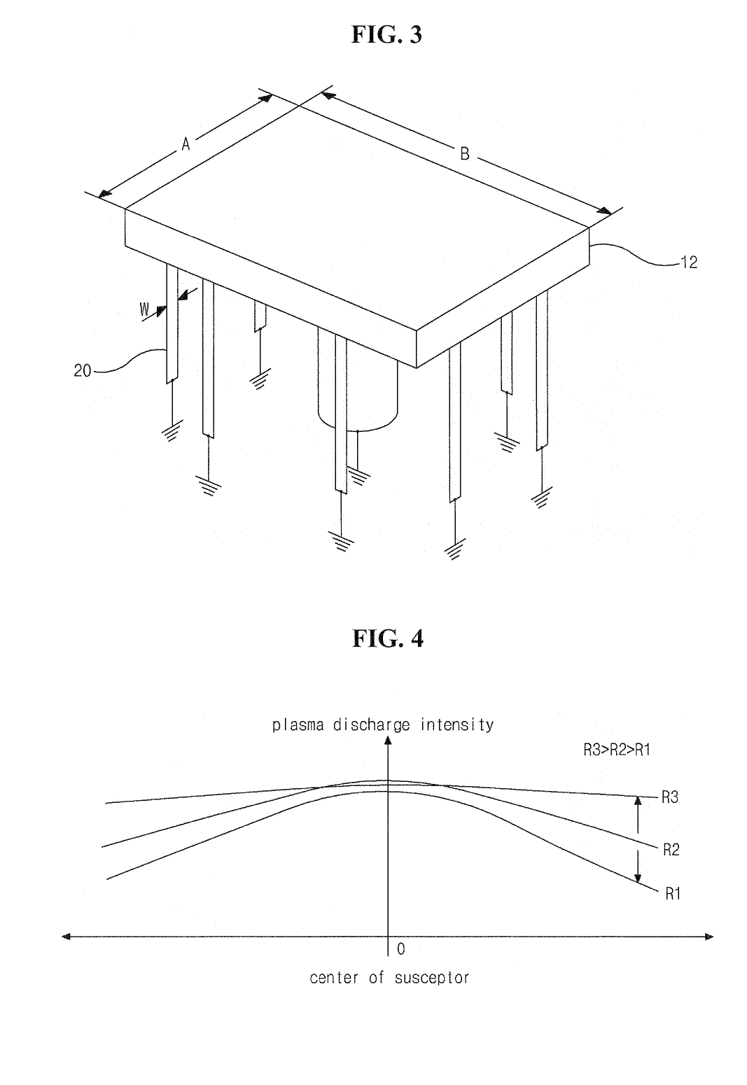

FIG. 2 is a view of schematically illustrating an apparatus of processing a substrate using a PECVD method according to the present invention.

In FIG. 2, the apparatus 10 includes a chamber 11 defining a reaction region. A susceptor 12 is disposed in the chamber 11, and a substrate S to be processed is loaded on the susceptor 12. The susceptor 12 is movable upward and downward by a shaft 12a connected to a center of the susceptor 12. A gas distributor 13 is disposed over the susceptor 12 in the chamber 11. An exhaust port 19 is formed at a lower wall of the chamber 11. Air or gases in the chamber 11 are exhausted through the exhaust port 19.

A plasma electrode 14 having a flat plate shape makes an upper part of the chamber 11 airtight. The plasma electrode 14 is disposed over the gas distributor 13, and the gas distributor 13 is fixed to the plasma electrode 14 at edges thereof. A diffusion region 15 is formed between the plasma electrode 14 and the gas distributor 13. A gas inlet 16 is formed at a center of the plasma electrode 14 and is connected to the diffusion region 15. Therefore, gases are injected through the gas inlet 16 and are diffused in the diffusion region 15.

An RF power source 18 is connected to the plasma electrode 14 and provides RF power to the plasma electrode 14. A matching system 17 is set up between the plasma electrode 14 and the RF power source 18 to adjust an impedance of the RF power provided to the plasma electrode 14.

Ground lines 20 are connected to peripheries of the susceptor 12 to earth the susceptor 12. The ground lines 20 may be connected to a bottom surface or a side surface of the susceptor 12 so that plasma generated over the susceptor 12 may not be affected. The shaft 12a is also grounded.

According to experiments, distribution of plasma discharge intensity over the susceptor 12 depends on a ratio of the ground lines 20 to the susceptor 12, which may be referred to as a ground line ratio R hereinafter.

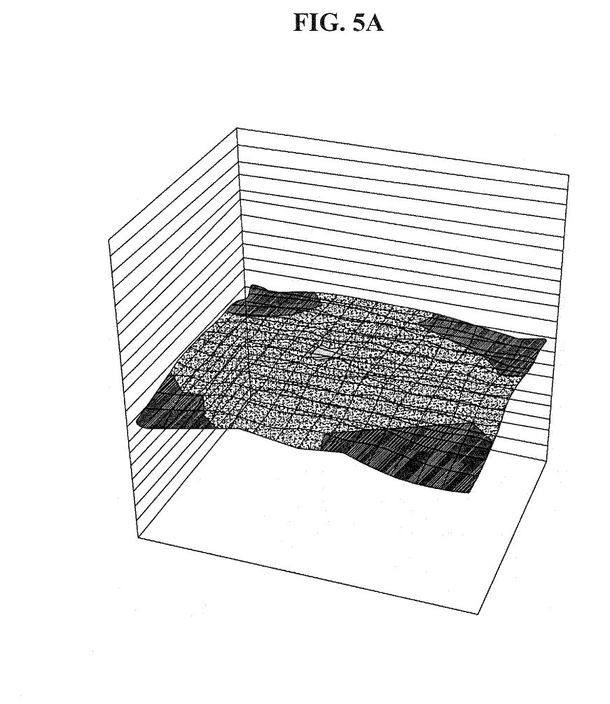

The ground line ratio R will be explained with reference to FIG. 3. FIG. 3 is a view of schematically illustrating a susceptor and ground lines connected thereto in the apparatus of FIG. 2. Since thicknesses of the ground lines are relatively very thin as compared with widths, for convenience of illustration, the ground lines are shown as sheets.

The ground line ratio R is a ratio of a total width of the ground lines 20 to a perimeter of the susceptor 12. Accordingly, when the susceptor 12 has a perimeter L and each ground lines 20 has a width W, the ground line ratio R is expressed by R=NW/L, wherein N is the number of the ground lines 20.

In FIG. 3, the susceptor 12 has a square shape of a width A and a length B. Therefore, the perimeter L of the susceptor 12 is 2(A+B). If the susceptor has a circular shape, the perimeter L of the susceptor is a circumference of a circle.

Two ground lines 20 are connected to each side of the bottom surface of the susceptor 12, and thus eight ground lines 20 are connected to the susceptor in total. Each ground line 20 may have a width W. The number of ground lines 20 may change.

Alternatively, the ground lines 20 may have different widths. In this case, the total width of the ground lines 20 is the sum of respective widths of the ground lines 20.

It is desirable that a distance between any adjacent two of the ground lines 20 is the same as others.

By the way, when the susceptor 12 has a square shape, a distance between the ground lines 20 adjacent along a length side of the susceptor 12 may be different from a distance between the ground lines 20 adjacent along a width side of the susceptor 12. In this case, beneficially, the ground lines 20 along the same side of the susceptor 12 are connected to the susceptor 12 with an equidistance therebetween.

According to the experiments, when the ground line ratio R is within a range of 2% to 15%, desirably, within a range of 3% to 10%, plasma is prevented under the susceptor 12, and plasma is uniformly generated over the susceptor 12. Here, inner pressure of the chamber 11 may be within a range of 0.1 Torr to 5 Torr, and the RF power may has a frequency of 13.56 MHz and an intensity of 200 mW/cm² to 700 mW/cm².

Generally, in the apparatus 10, since the RF power is supplied to the center of the plasma electrode 14, the plasma discharge intensity is high at a center region of the chamber 11 and decreases as it goes toward peripheries of the chamber 11.

On the other hand, when the ground line ratio R is within a range of 2% to 15%, the results of the experiments show increasing plasma discharge intensities according as the ground line ratios R increase.

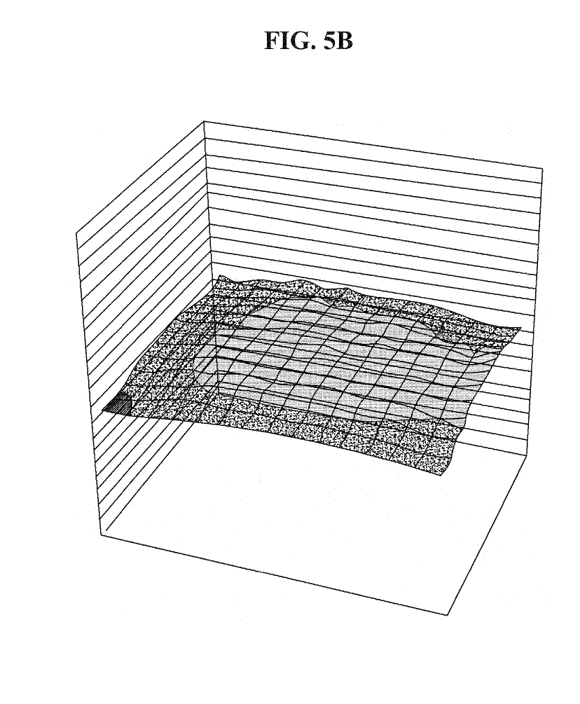

FIG. 4 is a view of illustrating the plasma discharge intensities to the ground line ratios R according to an exemplary embodiment of the present invention. In FIG. 4, the plasma discharge intensities are shown with respect to first, second and third ground line ratios R1, R2 and R3, wherein the first, second and third ground line ratios R1, R2 and R3 are within in range of 2% to 15% and satisfy the condition of R3>R2>R1. As shown in the figure, the plasma discharge intensity of the second ground line ratio R2 is larger than that of the first ground line ratio R1 at the peripheries of the chamber 11, and the plasma discharge intensity of the third ground line ratio R3 is larger than that of the second ground line ratio R2 at the peripheries of the chamber 11. The plasma discharge intensity of the third ground line ratio R3 is more uniform than those of the first and second plasma discharge intensities R1 and R2. Therefore, as the ground line ratio gets large, the plasma discharge intensity at the peripheries of the chamber 11 increases, and the uniformity of the plasma is improved.

Meanwhile, the plasma discharge intensity is directly connected to the plasma density, and thus the plasma discharge intensity affects a thickness of a thin film deposited on the substrate.

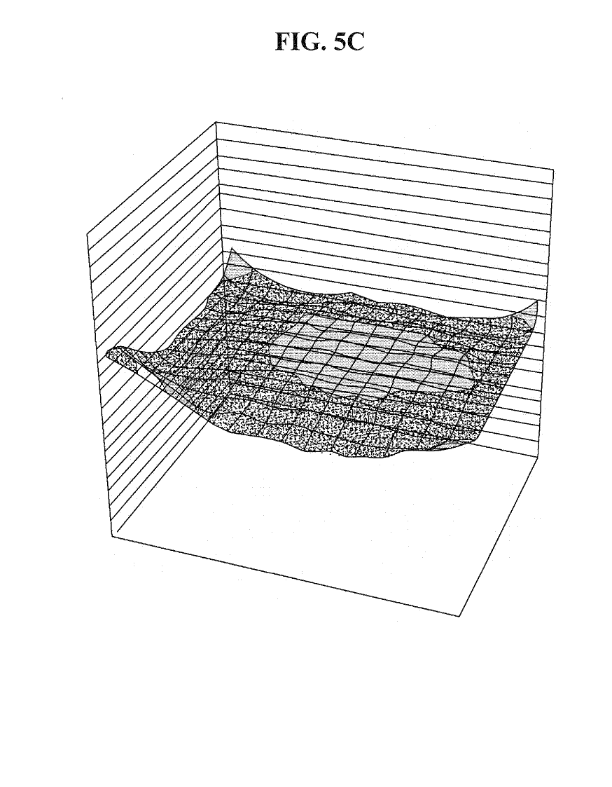

FIGS. 5A, 5B and 5C are views of illustrating thicknesses of thin films with respect to the ground line ratios R according to an exemplary embodiment of the present invention. In FIGS. 5A, 5B and 5C, thin films are formed on respective substrates, and thicknesses of the thin films are measured. The thicknesses of the thin films are shown with respect to first, second and third ground line ratios R1, R2 and R3, wherein the first, second and third ground line ratios R1, R2 and R3 are within in range of 2% to 15% and satisfy the condition of R3>R2>R1. As the ground line ratio increases, the thickness of the thin film grows at the periphery of the susceptor 12, and the uniformity of the thin film is improved.

Accordingly, in an apparatus of processing a substrate, the ground line ratio of a total width of ground lines to a perimeter of a susceptor, beneficially, is within a range of 2% to 15%. When a plasma discharge intensity of a chamber or uniformity of a thin film is needed to be adjusted, widths of the ground lines or the number of the ground lines may be changed in the above-mentioned ground line ratio.

In the meantime, the ground lines are connected to the bottom surface of the susceptor. Desirably, one ground line may be symmetrical to another with respect to the center of the susceptor. The number of the ground lines may be more than 6.

Moreover, in the present invention, even though the ground line ratio is defined as a ratio of the total width of the ground lines to the perimeter of the susceptor, a perimeter of the substrate may be substituted for the perimeter of the susceptor.

In the present invention, since distribution of the plasma may be controlled by adjusting the ratio of the ground lines to the susceptor, the plasma is prevented under the susceptor, and the uniformity of the plasma is improved over the susceptor. In addition, a thin film of a uniform thickness may be obtained.

It will be apparent to those skilled in the art that various modifications and variations can be made in the apparatus without departing from the spirit or scope of the invention. Thus it is intended that the present invention covers the modifications and variations of this invention provided they come within the scope of the appended claims and their equivalents.

What is claimed is:

1. An apparatus of processing a substrate, comprising:
a chamber;
a susceptor in the chamber;
a plasma-generating unit for generating plasma in the chamber;
a power source unit providing power to the plasma-generating unit; and
ground lines connected to peripheries of the susceptor,
wherein a ratio of a total width of the ground lines to a perimeter of the susceptor is within a range of 2% to 15%.

2. The apparatus according to claim 1, wherein the ground lines are symmetric with respect to a center of the susceptor.

3. The apparatus according to claim 1, wherein the ground lines are equidistant from one another.

4. The apparatus according to claim 1, wherein the susceptor has a square shape, and the ground lines that are disposed at a same side of the susceptor are equidistant from each other.

5. The apparatus according to claim 1, wherein the ground lines are connected to a bottom surface of the susceptor and a lower wall of the chamber.

6. The apparatus according to claim 1, wherein a substrate is disposed on the susceptor and is processed under a pressure of 0.1 Torr to 5 Torr.

7. The apparatus according to claim 1, wherein a substrate is disposed on the susceptor and is processed under a condition that an RF power of 200 mW/cm² to 700 mW/cm² is applied to the plasma-generating unit.
